(19) United States
(12) Patent Application Publication
(10) Pub. No.: US 2013/0196466 A1
(43) Pub. Date: Aug. 1, 2013

(54) METHOD AND APPARATUS FOR PRODUCING A TRANSPARENT CONDUCTIVE OXIDE

(71) Applicant: FIRST SOLAR, INC, Perrysburg, OH (US)

(72) Inventors: Zhibo Zhao, Novi, MI (US); Rui Shao, Sylvania, OH (US); Benyamin Buller, Sylvania, OH (US); Dale Roberts, Temperance, MI (US)

(73) Assignee: FIRST SOLAR, INC, Perrysburg, OH (US)

(21) Appl. No.: 13/754,613

(22) Filed: Jan. 30, 2013

Related U.S. Application Data
(60) Provisional application No. 61/592,339, filed on Jan. 30, 2012.

(51) Int. Cl. H01L 31/18

(52) U.S. Cl. CPC H01L 31/1884
USPC 438/96; 118/58; 118/641; 118/723 R

(57) ABSTRACT

A method and apparatus for manufacturing a multi-layered structure includes forming a crystalline layer of a material by depositing an amorphous layer of the material on a heated substrate.

This application claims the benefit of priority of U.S. Provisional Patent Application No. 61/592,339, filed Jan. 30, 2012, entitled: “Method and Apparatus for Producing a Transparent Conductive Oxide,” the entirety of which is incorporated by reference herein.

### FIELD OF THE INVENTION

The present invention relates to methods and apparatuses for producing a transparent conductive oxide for use in photovoltaic devices, such as photovoltaic cells and photovoltaic modules containing a plurality of photovoltaic cells.

### BACKGROUND OF THE INVENTION

A thin-film photovoltaic device often includes a transparent conductive oxide (“TCO”) material layer to conduct electrical charge, which is fabricated over a glass substrates One TCO material which is often used is crystalline cadmium stannate which has low sheet resistance and high light transmission for wavelengths in the solar spectrum.

A TCO layer may be sputtered onto an unheated glass substrate or onto a thin film layers previously deposited on an unheated glass substrate, resulting in an amorphous TCO film layer. The sputtered amorphous TCO film is then later annealed in an inert ambient atmosphere or sometimes in the presence of CdS vapor, at a temperature between 500° C. and 750° C. for at least 10 minutes. The annealing process transforms the deposited amorphous TCO material to a crystalline form.

While annealing an amorphous TCO layer is fairly easy in a laboratory setting, annealing an amorphous TCO layer can be rather difficult in a manufacturing setting. For example, in a manufacturing setting the amorphous TCO layer may be covered by another deposited layer before it is annealed. In such cases, it can be difficult to uniformly heat the amorphous TCO layer. If the amorphous TCO layer is not uniformly heated, it may not be uniformly transformed into a crystalline film. And, since the amorphous TCO layer is covered by another layer, it can be difficult to ensure that it has indeed been uniformly transformed into the crystalline film. The difficulty of uniformly heating a TCO layer is amplified when large scale photovoltaic devices, such as modules, are being fabricated because the size of the TCO layer in the photovoltaic device make it even more difficult to uniformly heat the TCO layer.

Further and as mentioned above, the amorphous TCO layer may have to be annealed at a temperature between 500° C. and 750° for at least 10 to 60 minutes. This is a rather high temperature sustained for a rather long duration of time to which the glass substrate upon which the TCO layer is deposited will be exposed. At such a high temperature, which may easily exceed the temperature at which the glass substrate may start to soften, and for such an extended period of time, the glass may start to crack, deteriorate or weaken. A photovoltaic device having such a damaged glass substrate may not meet its intended specifications and may not last as long as it should in operation.

Additionally, glass substrates that have been softened have a tendency to release an excessive amount of sodium in the form of sodium ions, which may diffuse into different layers of a completed photovoltaic device. Diffusion of sodium ions in certain layers of the photovoltaic device may decrease the device's efficiency.

Accordingly, a method of forming a TCO layer which obviates the afore-mentioned problems is desirable.

### BRIEF DESCRIPTION OF THE DRAWINGS

FIG. 1 is a schematic of a part of a photovoltaic device having multiple layers;

FIG. 2 is a schematic of a part of a photovoltaic device having multiple layers;

FIG. 3A is a schematic of a coating device;

FIG. 3B is a schematic of a coating device;

FIG. 3C is a schematic of a coating device;

FIG. 3D is a schematic of a coating device; and

FIG. 4 is a schematic of a photovoltaic device having multiple layers.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

Disclosed herein is a method of forming a TCO layer in a photovoltaic device that includes pre-heating a substrate, which may contain other layers deposited thereon, depositing an amorphous TCO material, for example, a material containing cadmium and tin (amorphous cadmium stannate), onto the pre-heated substrate, and allowing the pre-heated substrate to more directly condition the deposited amorphous TCO material, thereby partially or completely transforming the TCO layer from an amorphous layer into a crystalline layer. Such conditioning of the amorphous TCO layer may eliminate entirely the need for, or at least reduce, the temperature and/or time conventionally needed to anneal the amorphous TCO layer, which may in turn lessen possible damages to the substrate.

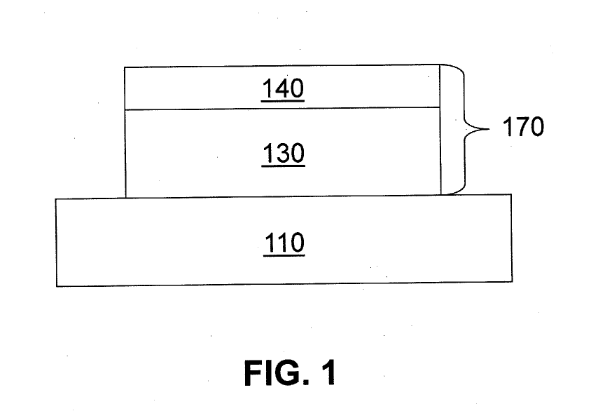

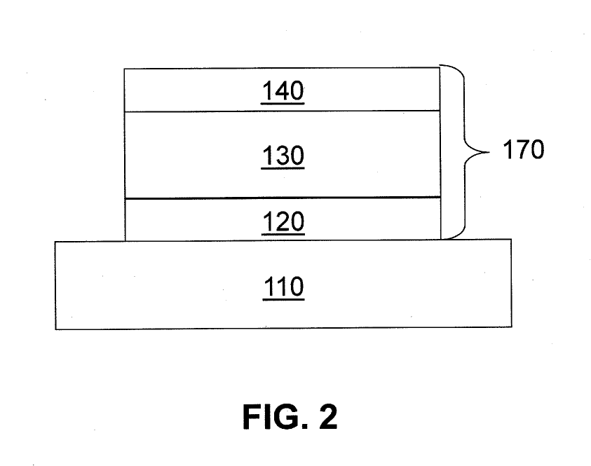

A TCO stack having a plurality of layers may be formed in a photovoltaic device through a series of manufacturing steps where each successive layer is formed adjacent to a previously formed layer on a substrate. For example, as shown in FIG. 1, a TCO stack 170 may include a plurality of layers deposited on a pre-heated substrate 110. The substrate 110 may be an optically transparent substrate, such as borosilicate glass, soda lime glass, or float glass. The TCO stack 170 may include an amorphous TCO layer 130 deposited on the pre-heated substrate 110 and a buffer layer 140 deposited on the TCO layer 130. Alternatively, as shown in FIG. 2, a barrier layer 120 may be deposited on the pre-heated substrate 110 before deposition of the TCO layer 130 and buffer layer 140. The barrier layer 120 may be of various materials such as a silicon nitride, silicon oxide, aluminum-doped silicon oxide, boron-doped silicon nitride, phosphorus-doped silicon nitride, silicon oxide-nitride, or any combination or alloy thereof. The buffer layer 140 may be made of various suitable materials, including tin oxide (e.g., a tin (IV) oxide), zinc tin oxide, zinc oxide, zinc oxysulfide, and zinc magnesium oxide.

As noted above, the TCO layer is formed by depositing TCO material directly on a pre-heated substrate or on a barrier layer deposited on a pre-heated substrate. The TCO layer may be deposited by any available technique, such as sputtering. Radiant heat from the pre-heated substrate directly conditions the deposited amorphous TCO layer by forming nano/micro crystallites within the material which, depending on the temperature of the pre-heated substrate, start or substantially complete the crystallization of the deposited TCO layer. The pre-heated temperature of the substrate may be in the range of 200° C. to 550° C. Although the upper portion of this temperature range (i.e., 500° C. to 550° C.) is still in the range of temperatures that, as described above, may damage the substrate, the substrate will not be exposed to those temperatures for the conventional 10 to 60 minutes during the substrate pre-heating. Usually, less than 2 minutes of substrate pre-heating is more than ample time, which then allows a post-deposition annealing of less than 10 minutes. Thus the combined pre-heating and annealing time may be less than or in the lower end of the conventional 10 to 60 minute annealing duration and, consequently, the substrate is less likely to be damaged during the annealing process.

The ultimate need for, or required temperature and/or duration of, the post-sputtering annealing process is proportional to the pre-heated temperature of the substrate. The greater the substrate pre-heating temperature, the lower the temperature and shorter the duration of the post deposition annealing process. Pre-heating the substrate to high-range temperatures, for example, above 400° C., will allow the substrate to provide enough radiant heat when the amorphous TCO layer is deposited on it to substantially crystallize the layer without a post-deposition annealing process. Alternatively, pre-heating the substrate to a mid-range temperature, for example, between about 300° C. and about 400° C., or a low-range temperature, for example between about 200° C. and about 300° C., will allow the substrate to provide enough radiant heat when the amorphous TCO layer is deposited on it to partially condition the TCO layer by forming nano/micro sized crystallites in the amorphous matrix. Although a post-sputtering annealing process may still be required to completely transform the TCO layer to a crystalline form, the post-sputtering annealing process may proceed at lower temperatures, that is, temperatures less than 550° C. and/or shorter heat exposure times, that is a times less than about 10 minutes.

It should be noted that radiant heat from a heated substrate 110 may condition a sputtered TCO layer 130 regardless of whether, as shown in FIG. 1, the TCO layer 130 is deposited directly on the pre-heated substrate 110, or whether, as shown in FIG. 2, additional layers, for example, a barrier layer 120, is deposited on the pre-heated substrate 110 before deposition of the TCO layer 130. Radiant heat from the pre-heated substrate 110 may pass through barrier layer 120 and still condition the TCO layer 130 to the same degree as when the TCO layer is deposited directly on the pre-heated substrate without the barrier layer 120.

In the exemplary embodiments described above, a variety of heating processes can be used alone to heat the substrate or in combination to incrementally heat the substrate to the desired temperature, which is usually between about 200° C. to about 550° C., prior to depositing the TCO layer.

Heating the substrate can be performed both outside (by external heating processes) and inside (by internal heating processes) of a TCO deposition chamber, for example, a sputtering coater. One initial heating process may include washing the substrate with a hot washing fluid, for example, water, which may have a temperature just below boiling point, for example, of at least 90° C., and raise the temperature of the substrate to about 90° C. Alternatively, or in addition to washing the substrate with a hot fluid, a heated drying gas can be directed at the substrate before the substrate enters the deposition chamber. The drying gas can have a temperature of up to 100° C. or greater to raise the temperature of the substrate to at least 100° C. Also, alternatively, or in addition to washing the substrate with a hot fluid and/or drying the substrate with the hot drying gas, a heater can be positioned near one or both surfaces of the substrate before it is transported into the deposition chamber to raise the temperature within the range of 200° C. to 550° C.

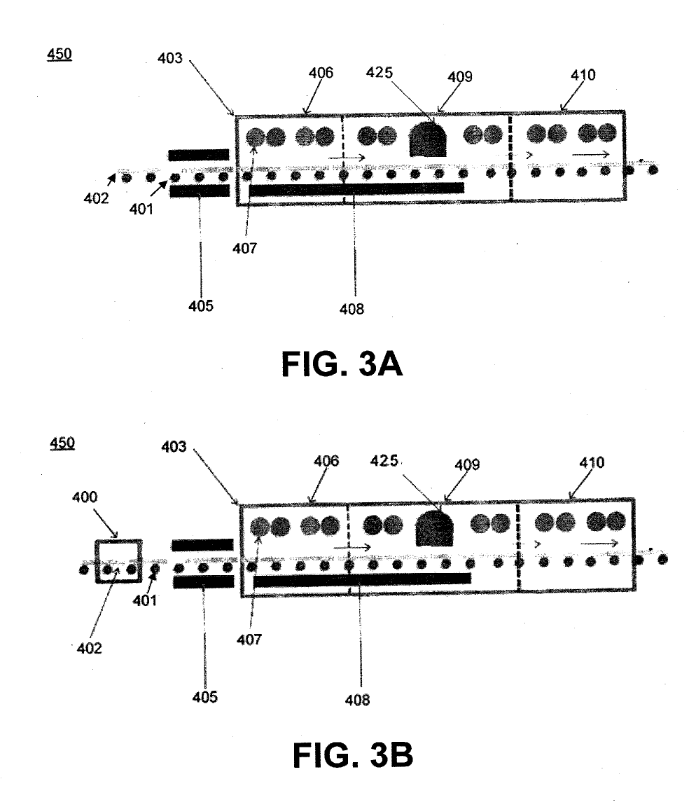

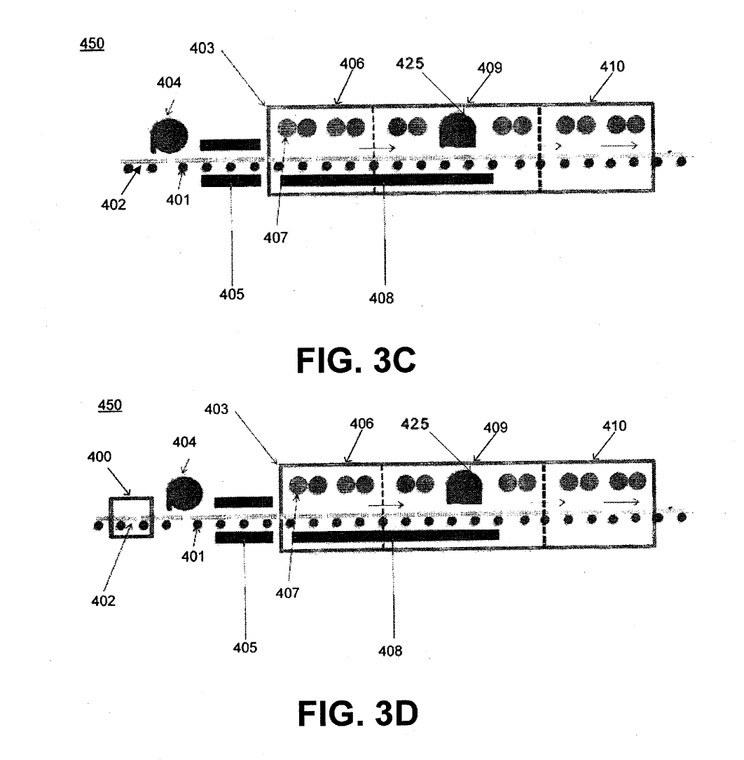

FIGS. 3A, 3B, 3C and 3D illustrate apparatuses for performing the methods described above. Referring to FIG. 3A, by way of example, a coating system 450 which provides for substrate heating may include a transporting conveyor system 401, for example, a roller conveyor, for transporting a substrate 110 into and through a deposition chamber 403, such as a sputtering coater apparatus for sputtering a TCO material onto the substrate 110. Substrate 110 may be conveyed by conveyor system 401 through a heater 405, positioned to provide heat to one or both surfaces of the substrate 110 to raise the temperature of the substrate 110 to 200° C. or greater prior to it being transported into deposition chamber 403. Alternatively, as illustrated in FIG. 3B, substrate 110 may be conveyed by conveyor system 401 through a washer 400 for cleaning the substrate 110. A hot washing fluid can be employed in washer 400 to heat the substrate 110 to at least 90° C. Then the conveyor system 401 may transport the substrate 110 to the heater 405, which may raise the temperature of the substrate from 90° C. to at least 200° C. In another embodiment, as illustrated in FIG. 3C, a heated drying gas is directed at the substrate 110 using a blowing apparatus 404, raising the substrate temperature to about 100° C. or greater. Then the conveyor system 401 may transport the substrate 110 to the heater 405, which may raise the temperature of the substrate from 100° C. to at least 200° C. In another embodiment, as illustrated in FIG. 3D, substrate 110 may be conveyed by conveyor system 401 through a washer 400 where the hot washing fluid can heat the substrate 110 to at least 90° C. Then a heated drying gas can be impinged on the substrate 110 using a blowing apparatus 404, raising the substrate temperature from 90° C. to about 100° C. or greater. Then the conveyor system 401 may transport the substrate 110 to the heater 405, which may raise the temperature of the substrate from 100° C. to at least 200° C.

Deposition chamber 403, as illustrated in FIGS. 3A-3D may include at least three zones (zones 406, 409 and 410). After being pre-heated, substrate 110 is transported by conveyor system 401 into zone 406. While in zone 406, substrate 110 may be further heated to a desired temperature, which in this case is in the range of about 200° C. to about 550° C. The heat can be supplied by various methods, including resistive heating, convective heating, and radiated heating, as indicated by heaters 407, 408. The heating element can be encased in a stainless steel sleeve that is hermetically sealed. Thin-film layers, for example, barrier layer 120 in FIG. 2, may be deposited on substrate 110 in zone 406 or in additional zones provided as needed between zone 406 and zone 409. If a separate zone is provided, it can be heated in the same manner as zone 406 to maintain the preheated temperature of substrate 110.

Preheated substrate 110 may then be transported by conveyor system 401 to zone 409. In zone 409, deposition of TCO material, for example, cadmium and tin, on heated substrate 110 is performed by deposition assembly 425 which may be a sputtering assembly. Zone 409 may also contain one or more heaters 407, 408 in the same manner as zone 406 to maintain the temperature of substrate 110. For a sputtered TCO material, sputtering plasma from deposition assembly 425 may also act as a heat source, for example, by reducing the distance between the deposition assembly 425 and the substrate 110. Sputtering plasma from the deposition assembly 425 will raise the substrate temperature of the substrate during deposition.

Coated substrate 110 may then be transported by conveyor system 401 to zone 410 where additional layers, for example, a buffer layer 140 as shown in FIGS. 1 and 2, may be applied. Zone 410 may also be heated in the same manner to maintain the temperature of the substrate. After completion of the deposition of the TCO layer on substrate 110, the coated substrate 110 may have further layers applied thereon in order to form a photovoltaic device. In any case, although not actually shown in the figures, at any point after the deposition of the TCO layer on the substrate 110, the TCO layer may be annealed via a post-deposition heating process to the extent required to complete crystallization.

It should be noted that the minimum temperature necessary to crystallize cadmium stannate as it is being deposited on a heated substrate is less than the minimum temperature that may be used in the conventional annealing method, specifically, 400° C. as opposed to 500° C. This is because crystallization occurs more easily as the material is being deposited and heat is being applied to it than depositing the material first and then applying heat to it.

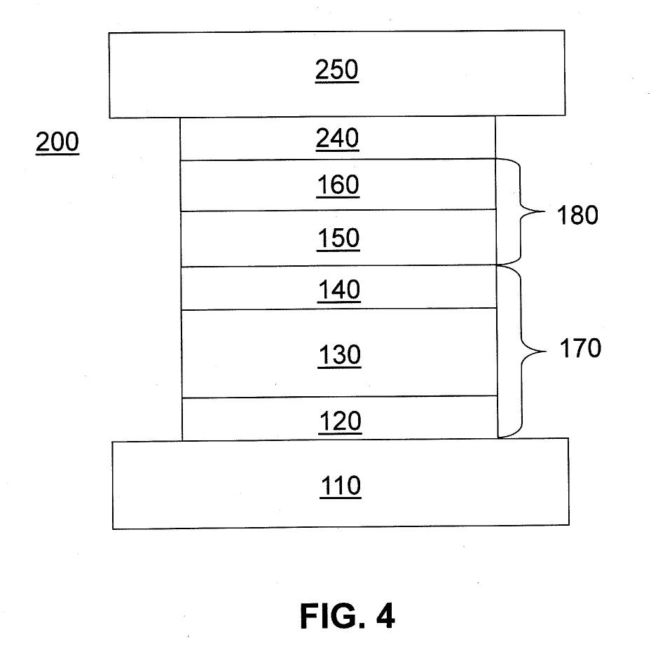

A TCO stack 170 deposited on a heated substrate 110 with a buffer layer 140, a TCO layer 130, and an optional barrier layer 120, as described above, may be incorporated into a photovoltaic device 200, as shown in FIG. 4. Photovoltaic device 200 may further include a semiconductor stack 180, which may include a semiconductor window layer 150 deposited adjacent the buffer layer 140 and a semiconductor absorber layer 160 deposited adjacent to the semiconductor window layer 150. Both the semiconductor window layer 150 and the semiconductor absorber layer 160 can be deposited using any known deposition technique, including closed spaced sublimation (CSS) and vapor transport deposition (VTD) after the TCO layer has been deposited on the heated substrate 110 as described above. The semiconductor window layer 150 can be a cadmium sulfide layer. Semiconductor absorber layer 160 can include a cadmium telluride, copper indium diselenide, copper indium disulfide, copper indium aluminum diselenide, or copper indium gallium diselenide (CIGS) layer. Photovoltaic device 200 may further include a back contact (electrode) 240 deposited adjacent to semiconductor absorber layer 160 of the semiconductor stack 180 and a back support 250, for example, a glass plate, can be placed adjacent to back contact 240.

The embodiments described above are offered by way of illustration and example. It should be understood that the examples provided above may be altered in certain respects and still remain within the scope of the claims. It should be appreciated that, while the invention has been described with reference to the above exemplary embodiments, other embodiments are within the scope of the claims.

What is claimed as new and desired to be protected by Letters Patent of the United States is:

1. A method of forming a crystalline layer on a substrate comprising:
pre-heating the substrate; and
depositing an amorphous material on the pre-heated substrate such that radiant heat from the substrate transforms the amorphous material to a crystalline form.

2. The method of claim 1, wherein as part of said pre-heating, the substrate is washed with a heated fluid.

3. The method of claim 1, wherein as part of said pre-heating, the substrate is heated by a heated gas.

4. The method of claim 1, wherein as part of said pre-heating, the substrate is brought into the vicinity of a heater before the amorphous material is deposited.

5. The method of claim 4, wherein the heater is disposed outside a chamber in which the amorphous material is deposited.

6. The method of claim 4, wherein the heater is disposed inside the chamber in which the amorphous material is deposited.

7. The method of claim 1, wherein said depositing occurs by sputtering and as part of said pre-heating, the substrate is heated by sputtering plasma.

8. The method of claim 1, wherein said pre-heating comprises:
washing the substrate with a heated fluid;
impinging a heated gas on the substrate; and
bringing the substrate into the vicinity of a heater,
wherein washing the substrate, impinging the heated gas on the substrate, and bringing the substrate into the vicinity of the heater incrementally raises the temperature of the substrate.

9. The method of claim 8, wherein said depositing occurs by sputtering and as part of said heating, the substrate is pre-heated by sputtering plasma.

10. The method of claim 1, wherein the substrate is pre-heated to a temperature of about 200° C. to about 550° C.

11. The method of claim 1, wherein the substrate is pre-heated to a temperature of at least about 400° C.

12. The method of claim 1, wherein the substrate is pre-heated to a temperature of about 200° C. to about 400° C.

13. The method of claim 10, wherein the amorphous material is cadmium stannate.

14. The method of claim 13, wherein the method further comprises:
depositing a semiconductor window layer on a stack containing the crystalline layer; and
depositing a semiconductor absorber layer on the semiconductor window layer.

15. The method of claim 14, wherein the semiconductor window layer comprises cadmium sulfide.

16. The method of claim 15, wherein the semiconductor absorber layer comprises cadmium telluride.

17. The method of claim 15, wherein the semiconductor absorber layer comprises copper indium gallium diselenide.

18. The method of claim 15, wherein the semiconductor absorber layer comprises copper indium diselenide.

19. The method of claim 15, wherein the semiconductor absorber layer comprises copper indium disulfide.

20. The method of claim 15, wherein the semiconductor absorber layer comprises copper indium aluminum diselenide.

21. The method of claim 1, wherein said depositing occurs by sputtering.

22. An apparatus for forming a photovoltaic device comprising:
a heater system for pre-heating a substrate to a temperature; and
a deposition station for depositing an amorphous material on the pre-heated substrate.

23. The apparatus of claim 22 further comprising:
a conveyor system for transporting the substrate through the heater system and the deposition station.

24. The apparatus of claim 23, wherein the deposition station further comprises:
a deposition chamber; and
a deposition unit within the deposition chamber for depositing the amorphous material on the pre-heated substrate.

25. The apparatus of claim 24, wherein the deposition unit is configured to sputter the amorphous material on the pre-heated substrate.

26. The apparatus of claim 24, wherein the heater system further comprises at least one heater inside the deposition chamber for pre-heating the substrate with radiant heat and maintaining the temperature of the substrate during deposition.

27. The apparatus of claim 24, wherein the heater system further comprises:
a washer outside of the deposition chamber for pre-heating the substrate with a heated fluid;
a blower outside of the deposition chamber for pre-heating the substrate with a heated gas; and
at least one heater outside of the deposition chamber for pre-heating the substrate with radiant heat.

28. The apparatus of claim 24, wherein the deposition unit further comprises a sputtering plasma that heats the substrate during a sputtering of the amorphous material on the substrate.

29. The apparatus of claim 23, wherein the substrate is a barrier layer coated glass.

30. The apparatus of claim 23, wherein the amorphous material is cadmium stannate.

31. The apparatus of claim 23, wherein the heater system pre-heats the substrate to a temperature of about 200° C. to about 550° C.

32. The apparatus of claim 23, wherein the heater system pre-heats the substrate to a temperature of at least about 400° C.
